(19) United States
(12) Patent Application Publication
(10) Pub. No.: US 2026/0243982 A1
(43) Pub. Date: Aug. 20, 2026

(54) OPTICAL MODULE

(71) Applicant: HISENSE BROADBAND MULTIMEDIA TECHNOLOGIES CO., LTD., Qingdao (CN)

(72) Inventors: Long ZHENG, Qingdao (CN); Haiqiang XU, Qingdao (CN); Wanju SUN, Qingdao (CN); Sigeng YANG, Qingdao (CN); Fenglai WANG, Qingdao (CN); Chunyun YUE, Qingdao (CN); Lin WANG, Qingdao (CN); Hao TIAN, Qingdao (CN); Xiangyu DING, Qingdao (CN)

(21) Appl. No.: 19/641,108

(22) Filed: Apr. 7, 2026

Related U.S. Application Data
(63) Continuation of application No. PCT/CN2024/081908, filed on Mar. 15, 2024.

(30) Foreign Application Priority Data
Oct. 8, 2023 (CN) 202322688727.0
Oct. 8, 2023 (CN) 202322693819.8
Oct. 18, 2023 (CN) 202311354670.9

(51) Int. Cl. G02B 6/42; H01S 3/10; H01S 3/13

(52) U.S. Cl. CPC G02B 6/428; G02B 6/4267; G02B 6/4278; H01S 3/10015; H01S 3/1305

(57) ABSTRACT

An optical module including a circuit board, a substrate, a heater and a laser chip mounted on the substrate. The circuit board is provided with a signal line and a ground pad. The substrate is provided with a high-frequency transmission line wire-bonded to the signal line and a ground metal region wire-bonded to the ground pad. The laser chip is mounted on the ground metal region and wire-bonded to the high-frequency transmission line. The heater is thermally isolated from the substrate and has a first power supply terminal electrically connected to the circuit board to transmit a driving current to the heater, a second power supply terminal electrically connected to the circuit board, and a ground terminal connected to the ground metal region. The heater is connected to the laser chip via a gold wire to transmit the driving current and conduct heat to the laser chip.

The present application is a continuation of International Application No. PCT/CN2024/081908, filed on Mar. 15, 2024, which claims priority to Chinese Patent Application No. 202311354670.9, filed with the China National Intellectual Property Administration on Oct. 18, 2023, to Chinese Patent Application No. 202322688727.0, filed with the China National Intellectual Property Administration on Oct. 8, 2023, and to Chinese Patent Application No. 202322693819.8, filed with the China National Intellectual Property Administration on Oct. 8, 2023, the entire contents of all the above-mentioned applications are incorporated herein by reference.

### FIELD OF THE INVENTION

The present disclosure relates to the field of optical fiber communication technology, and in particular, to an optical module.

### BACKGROUND OF THE INVENTION

With the development of new services and application models such as cloud computing, mobile Internet, and video, advances in optical communication technology have become increasingly important. In optical communication technology, the optical module is a tool for conversion between optical and electrical signals, and it is one of the key devices in optical communication equipment. Furthermore, as the demand for the development of optical communication technology increases, the transmission rate of optical modules continues to rise.

### SUMMARY OF THE INVENTION

An embodiment of the present disclosure provides an optical module, including:
a circuit board, provided with a signal line, a first pad, a second pad, and a ground pad;
a substrate, provided with a high-frequency transmission line and a ground metal region, where the high-frequency transmission line is wire-bonded to the signal line, and the ground metal region is wire-bonded to the ground pad;
a heater, mounted on the substrate, where the heater is thermally isolated from the substrate, the heater includes a heating resistor and a thermally conductive plate, the heating resistor is configured to generate heat, the thermally conductive plate covers the heating resistor, one side of the thermally conductive plate in contact with the heating resistor is insulated, and one side of the thermally conductive plate away from the heating resistor is plated with a metal layer;
a laser chip, mounted on the ground metal region, where the heater is located on one side of the laser chip, and the laser chip is wire-bonded to the high-frequency transmission line and configured to generate an optical signal; and
a first matching resistor, disposed on the substrate, where one terminal of the first matching resistor is wire-bonded to the laser chip, and the other terminal thereof is wire-bonded to the ground metal region, to achieve impedance matching between the laser chip and the high-frequency transmission line;
where
the substrate is further provided with a first power supply transmission line and a second power supply transmission line;
the second power supply transmission line electrically connects the second pad to the heating resistor to transmit a heating current output from the second pad to the heating resistor, thereby enabling the heating resistor to operate and generate heat; and
the first power supply transmission line electrically connects the first pad to the metal layer, and the metal layer is connected to the laser chip via a gold wire, to transmit a driving current output from the first pad to the laser chip and conduct the heat generated by the heating resistor to the laser chip.

In some embodiments of the present disclosure, the circuit board is provided with:
a laser bias circuit, connected at one terminal to a first power supply terminal and configured to output a direct-current drive signal to an optical transmitter chip;
a sampling resistor, located between the laser bias circuit and the laser chip;
an operational amplifier chip, having a first input terminal connected to a first terminal of the sampling resistor and a second input terminal connected to a second terminal of the sampling resistor; and
a microcontroller unit (MCU), connected to an output terminal of the operational amplifier chip and configured to receive a voltage difference of the sampling resistor and convert the voltage difference into a bias current value for reading by a host computer,
where the MCU is further connected to the laser bias circuit, and the MCU controls turn-on and turn-off of the laser bias circuit and controls a magnitude of an output voltage of the laser bias circuit.

### BRIEF DESCRIPTION OF THE DRAWINGS

To illustrate the technical solutions in the present disclosure more clearly, a brief introduction to the drawings that need to be used in some embodiments of the present disclosure will be provided below. Apparently, the drawings described below are merely the drawings in some embodiments of the present disclosure. Those of ordinary skill in the art can also derive other drawings from these drawings. Furthermore, the drawings described below can be regarded as schematic diagrams and are not intended to limit the actual dimensions of the products, the actual processes of the methods, or the actual timing of the signals involved in the embodiments of the present disclosure.

FIG. 1 is a partial structural diagram of an optical communication system according to some embodiments of the present disclosure;

FIG. 2 is a partial structural diagram of a host computer according to some embodiments of the present disclosure;

FIG. 3 is a structural diagram of an optical module according to some embodiments of the present disclosure;

FIG. 4 is an exploded view of an optical module according to some embodiments of the present disclosure;

FIG. 5 is a partial structural diagram of an optical module according to some embodiments of the present disclosure;

FIG. 6 is atop view of a connection between a laser chip and a circuit board in an optical module according to some embodiments of the present disclosure;

FIG. 7 is a top view of wire bonding of a laser in an optical module according to some embodiments of the present disclosure;

FIG. 8 is a first partial enlarged view of wire bonding of a laser in an optical module according to some embodiments of the present disclosure;

FIG. 9 is a second partial enlarged view of wire bonding of a laser in an optical module according to some embodiments of the present disclosure;

FIG. 10 is a structural diagram of a heater in an optical module according to some embodiments of the present disclosure;

FIG. 11 is an exploded view of a heater in an optical module according to some embodiments of the present disclosure;

FIG. 12 is a wire bonding diagram of a laser and a heater in an optical module according to some embodiments of the present disclosure;

FIG. 13 is a schematic diagram of an electrical connection of a laser in an optical module according to some embodiments of the present disclosure;

FIG. 14 is a schematic diagram of a partial structure of an optical module according to some embodiments of the present disclosure;

FIG. 15 is a schematic diagram of a partial signal flow in an optical module according to some embodiments of the present disclosure;

FIG. 16 is a schematic structural diagram of a microcontroller unit (MCU) according to some embodiments of the present disclosure;

FIG. 17 is a schematic diagram of a signal flow in an optical module according to some embodiments of the present disclosure;

FIG. 18 is a second schematic structural diagram of an optical module according to some embodiments of the present disclosure; and

FIG. 19 is a third schematic structural diagram of an optical module according to some embodiments of the present disclosure.

### DETAILED DESCRIPTION OF THE EMBODIMENTS

The following describes some embodiments of the present disclosure clearly and in detail with reference to the drawings. However, the described embodiments are some but not all of the embodiments of the present disclosure. All other embodiments obtained by those of ordinary skill in the art based on the embodiments provided in the present disclosure fall within the scope of protection of the present disclosure.

Unless otherwise required by the context, throughout the specification and the claims, the term “include/comprise” is interpreted as open and inclusive, meaning “including/comprising, but not limited to”; the terms “first” and “second” should not be construed as indicating or implying relative importance or indicating an upper limit on quantity; the term “a plurality of” means two or more; the term “connection” should be understood broadly, for example, “connection” may be a fixed connection, a detachable connection, or an integral connection, or may be directly connected, or indirectly connected via an intermediate medium; the term “adapted to” or “configured to” is an open and inclusive language, and does not exclude devices adapted or configured to perform additional tasks or steps; and the terms “parallel,” “vertical,” “same,” “consistent,” “flush,” etc. are not limited to absolute mathematical theoretical relationships, but also include acceptable error ranges arising in practice, as well as differences formed due to manufacturing reasons based on the same design concept.

In optical communication technology, to establish information transmission between information processing devices, it is necessary to load information onto light and use the propagation of light to achieve the transmission of information. Here, the light loaded with information is an optical signal. When the optical signal is transmitted in the information transmission devices, the loss of optical power can be reduced, such that high-speed, long-distance, and low-cost information transmission can be achieved. The signals that the information processing devices are able to recognize and process are electrical signals. The information processing devices usually include optical network units (ONUs), gateways, routers, switches, mobile phones, computers, servers, tablet computers, televisions, etc. The information transmission devices usually include optical fibers and optical waveguides.

The optical modules enable the conversion between optical signals and electrical signals from the information processing devices and the information transmission devices. For example, at least one of an optical signal input or an optical signal output of an optical module is connected to an optical fiber, and at least one of an electrical signal input or an electrical signal output of the optical module is connected to an optical network unit; a first optical signal from the optical fiber is transmitted to the optical module, and the optical module converts the first optical signal into a first electrical signal and transmits the first electrical signal to the optical network unit; and a second electrical signal from the optical network unit is transmitted to the optical module, and the optical module converts the second electrical signal into a second optical signal and transmits the second optical signal to the optical fiber. Since information can be transmitted through electrical signals between a plurality of information processing devices, at least one information processing device in the plurality of information processing devices is required to be directly connected to the optical module, and all information processing devices are not required to be directly connected to the optical module. Here, the information processing device directly connected to the optical module is referred to as a host computer of the optical module. In addition, the optical signal input or the optical signal output of the optical module can be referred to as an optical port, and the electrical signal input or the electrical signal output of the optical module can be referred to as an electrical port.

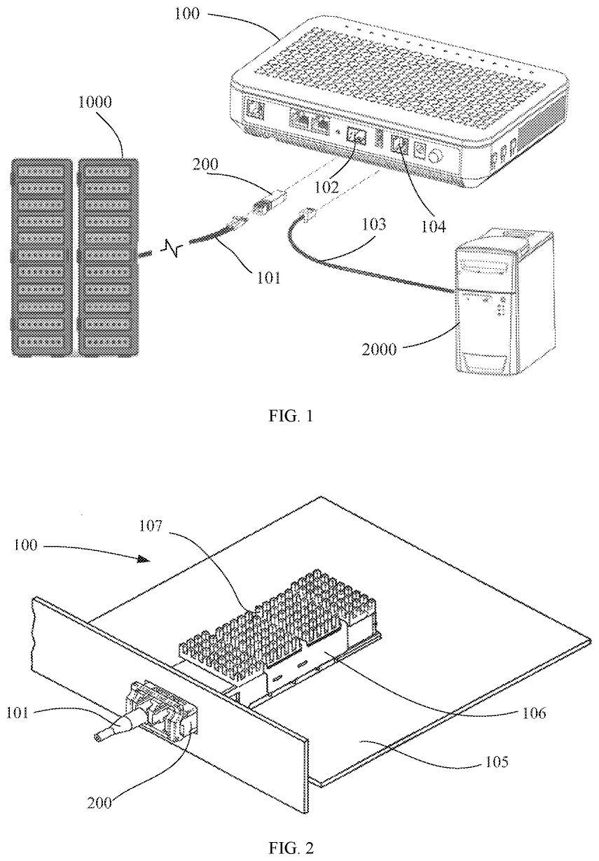

FIG. 1 is a partial structural diagram of an optical communication system according to some embodiments of the present disclosure. As shown in FIG. 1, the optical communication system primarily includes a remote information processing device 1000, a local information processing device 2000, a host computer 100, an optical module 200, an optical fiber 101, and a network cable 103.

One end of the optical fiber 101 extends toward the remote information processing device 1000, and the other end of the optical fiber 101 is connected to the optical module 200 via an optical port of the optical module 200. An optical signal can undergo total reflection in the optical fiber 101, and the propagation of the optical signal in the total reflection direction can nearly maintain its original optical power. The optical signal undergoes multiple total reflections in the optical fiber 101 to transmit an optical signal from the remote information processing device 1000 to the optical module 200 or to transmit an optical signal from the optical module 200 to the remote information processing device 1000, thereby achieving long-distance and low-power-loss information transmission.

The optical communication system may include one or more optical fibers 101, and the optical fiber 101 is detachably or fixedly connected to the optical module 200. The host computer 100 is configured to provide a data signal to the optical module 200, receive a data signal from the optical module 200, or monitor or control an operating state of the optical module 200.

The host computer 100 includes a generally cuboid-shaped housing and an optical module interface 102 disposed on the housing. The optical module interface 102 is configured to be connected to the optical module 200, enabling the host computer 100 to establish a one-way or two-way electrical signal connection with the optical module 200.

The host computer 100 further includes an external electrical interface that can be connected to an electrical signal network. For example, the external electrical interface includes a universal serial bus (USB) interface or a network cable interface 104. The network cable interface 104 is configured to be connected to the network cable 103, enabling the host computer 100 to establish a one-way or two-way electrical signal connection with the network cable 103. One end of the network cable 103 is connected to the local information processing device 2000, and the other end of the network cable 103 is connected to the host computer 100, thereby establishing an electrical signal connection between the local information processing device 2000 and the host computer 100 via the network cable 103. For example, a third electrical signal sent by the local information processing device 2000 is transmitted into the host computer 100 via the network cable 103. The host computer 100 generates a second electrical signal based on the third electrical signal. The second electrical signal from the host computer 100 is transmitted to the optical module 200. The optical module 200 converts the second electrical signal into a second optical signal and transmits the second optical signal to the optical fiber 101. The second optical signal is transmitted through the optical fiber 101 to the remote information processing device 1000. For example, a first optical signal from the remote information processing device 1000 is transmitted through the optical fiber 101. The first optical signal from the optical fiber 101 is transmitted to the optical module 200. The optical module 200 converts the first optical signal into a first electrical signal, and then the optical module 200 transmits the first electrical signal to the host computer 100. The host computer 100 generates a fourth electrical signal based on the first electrical signal and transmits the fourth electrical signal to the local information processing device 2000. It should be noted that the optical module is a tool to achieve the conversion between optical signals and electrical signals. During the conversion between the optical signals and the electrical signals, the information remains unchanged, and the encoding and decoding methods for the information may vary.

In addition to the optical network unit, the host computer 100 further includes an optical line terminal (OLT), an optical network terminal (ONT), or a data center server.

FIG. 2 is a partial structural diagram of a host computer according to some embodiments of the present disclosure. To clearly show the connection relationship between the optical module 200 and the host computer 100, FIG. 2 shows only the structure of the host computer 100 related to the optical module 200. As shown in FIG. 2, the host computer 100 further includes a printed circuit board (PCB) 105 disposed in the housing, a cage 106 disposed on a surface of the PCB 105, a heat sink 107 disposed on the cage 106, and an electrical connector disposed inside the cage 106. The electrical connector is configured to be connected to the electrical port of the optical module 200. The heat sink 107 has protruding structures such as fins that enlarge the heat dissipation area.

The optical module 200 is inserted into the cage 106 of the host computer 100, and the optical module 200 is fixed by the cage 106. The heat generated by the optical module 200 is conducted to the cage 106 and then diffused through the heat sink 107. After the optical module 200 is inserted into the cage 106, the electrical port of the optical module 200 is connected to the electrical connector inside the cage 106, such that the optical module 200 establishes a two-way electrical signal connection with the host computer 100. In addition, the optical port of the optical module 200 is connected to the optical fiber 101, such that the optical module 200 establishes a two-way optical signal connection with the optical fiber 101.

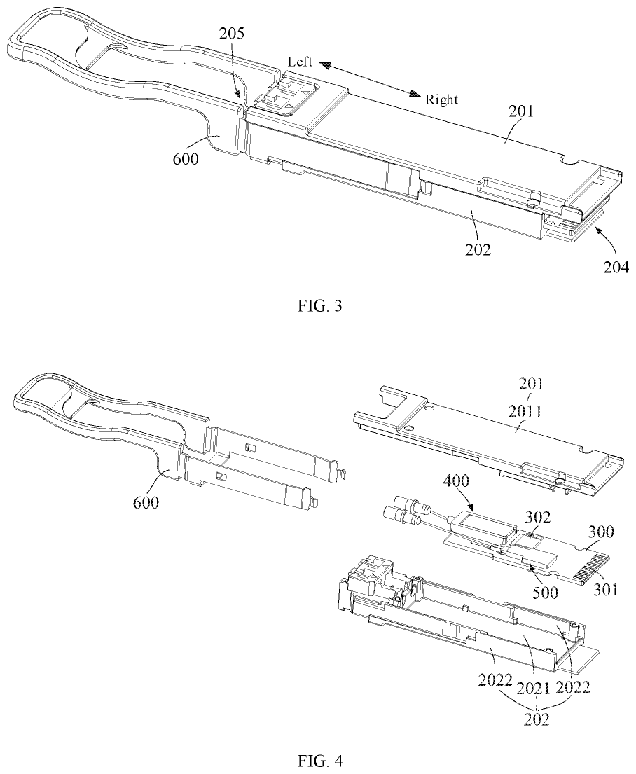

FIG. 3 is a structural diagram of an optical module according to some embodiments of the present disclosure. FIG. 4 is an exploded view of an optical module according to some embodiments of the present disclosure. As shown in FIG. 3 and FIG. 4, the optical module 200 includes a shell, and a circuit board 300, an optical transmitter component 400 and an optical receiver component 500 disposed in the shell. However, the present disclosure is not limited to this. In some embodiments, the optical module 200 includes either an optical transmitter component 400 or an optical receiver component 500.

The shell includes an upper shell 201 and a lower shell 202, where the upper shell 201 covers the lower shell 202 to form the shell with an opening 204 and an opening 205; and the outer contour of the shell is generally square.

In some embodiments, the lower shell 202 includes a bottom plate 2021 and two lower side plates 2022 located on two sides of the bottom plate 2021 and perpendicular to the bottom plate 2021; and the upper shell 201 includes a cover plate 2011, where the cover plate 2011 covers the two lower side plates 2022 of the lower shell 202 to form the shell.

In some embodiments, the lower shell 202 includes a bottom plate 2021 and two lower side plates 2022 located on two sides of the base plate 2021 and perpendicular to the bottom plate 2021; and the upper shell 201 includes a cover plate 2011 and two upper side plates located on two sides of the cover plate 2011 and perpendicular to the cover plate 2011, where the two upper side plates and the two lower side plates 2022 are combined to ensure that the upper shell 201 covers the lower shell 202.

The direction of a line connecting the opening 204 to the opening 205 may be consistent or inconsistent with the length direction of the optical module 200. For example, the opening 204 is located at an end of the optical module 200 (the right end in FIG. 3), and the opening 205 is also located at an end of the optical module 200 (the left end in FIG. 3). Alternatively, the opening 204 is located at an end of the optical module 200, and the opening 205 is located on a side of the optical module 200. The opening 204 is an electrical port. A gold finger 301 of the circuit board 300 extends from the electrical port and is inserted into the electrical connector of the host computer 100. The opening 205 is an optical port configured to be connected to the external optical fiber 101, such that the optical fiber 101 connects the optical transmitter component 400 and the optical receiver component 500 in the optical module 200.

An assembly method for combining the upper shell 201 with the lower shell 202 is adopted, such that the circuit board 300, the optical transmitter component 400, the optical receiver component 500, and other components can be conveniently mounted in the shell. These components can be encapsulated and protected by the upper shell 201 and lower shell 202. In addition, when the circuit board 300, the optical transmitter component 400, the optical receiver component 500, and other components are assembled, the deployment of positioning components, heat dissipation components, and electromagnetic shielding components of these components is facilitated, which is conducive to automated production.

In some embodiments, the upper shell 201 and the lower shell 202 are made of metal, which is conducive to electromagnetic shielding and heat dissipation.

In some embodiments, the optical module 200 further includes an unlocking component 600 located outside its shell. The unlocking component 600 is configured to establish or release a fixed connection between the optical module 200 and the host computer.

For example, the unlocking component 600 is located outside the two lower side plates 2022 of the lower shell 202, and includes an engaging component that matches the cage 106 of the host computer 100. When the optical module 200 is inserted into the cage 106, the optical module 200 is fixed in the cage 106 by the engaging component of the unlocking component 600. When the unlocking component 600 is pulled, the engaging component of the unlocking component 600 moves accordingly, thereby changing the connection relationship between the engaging component and the host computer to release the fixation between the optical module 200 and the host computer, such that the optical module 200 can be withdrawn from the cage 106.

The circuit board 300 includes circuit traces, electronic components, and chips, where the electronic components and the chips are connected according to the circuit design through the circuit traces to implement the functions such as power supply, electrical signal transmission, and grounding. The electronic components may include, for example, capacitors, resistors, transistors, and metal-oxide-semiconductor field-effect transistors (MOSFETs). The chips may include, for example, microcontroller units (MCUs), laser driving chips, transimpedance amplifiers (TIAs), limiting amplifiers (LAs), clock and data recovery (CDR) chips, power management chips, and digital signal processing (DSP) chips.

The circuit board 300 is generally a rigid circuit board. The rigid circuit board can also serve a load-bearing function due to its relatively rigid material, for example, the rigid circuit board can smoothly carry the aforementioned electronic components and chips. The rigid circuit board can also be inserted into the electrical connector in the cage 106 of the host computer 100.

The circuit board 300 further includes a gold finger 301 formed on an end surface thereof, where the gold finger 301 is composed of a plurality of mutually independent pins. The circuit board 300 is inserted into the cage 106, and the gold finger 301 is connected to the electrical connector in the cage 106. The gold finger 301 may be disposed on only one surface of the circuit board 300 (e.g., the upper surface shown in FIG. 4), or may be disposed on the upper and lower surfaces of the circuit board 300 to provide more pins, thereby adapting to scenarios requiring a large number of pins. The gold finger 301 is configured to establish an electrical connection with the host computer to achieve power supply, grounding, two-wire inter-integrated circuit (I2C) signal transmission, data signal transmission, etc. Certainly, flexible circuit boards are also used in some optical modules. Flexible circuit boards are generally used in conjunction with rigid circuit boards as a supplement to rigid circuit boards.

At least one of the optical transmitter component 400 or the optical receiver component 500 is located on one side of the circuit board 300 away from the gold finger 301.

In some embodiments, the optical transmitter component 400 and the optical receiver component 500 are physically separated from the circuit board 300 and then are electrically connected to the circuit board 300 via corresponding flexible circuit boards or electrical connectors.

In some embodiments, at least one of the optical transmitter component 400 or the optical receiver component 500 may be directly disposed on the circuit board 300. For example, at least one of the optical transmitter component 400 or the optical receiver component 500 may be disposed on a surface or a side edge of the circuit board 300.

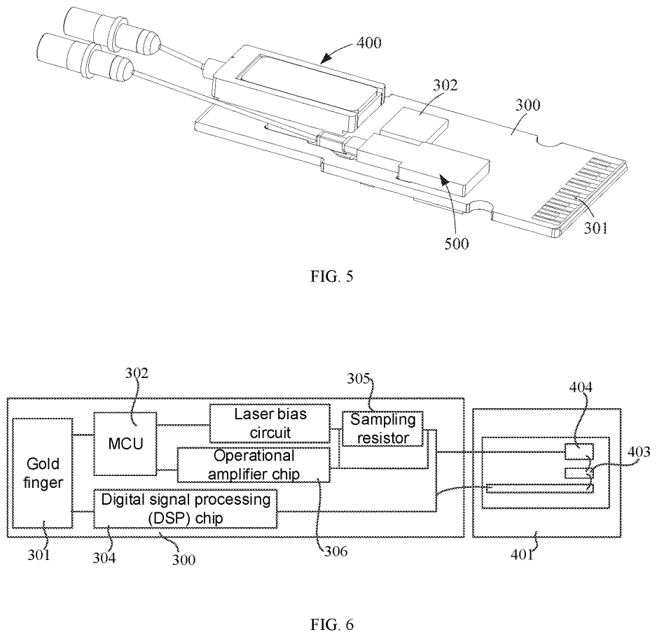

FIG. 5 is a partial structural diagram of an optical module provided according to some embodiments of the present disclosure. As shown in FIG. 5, the optical transmitter component 400 generally includes components such as a transmitter shell, a laser chip, and a lens assembly. The transmitter shell can be directly mounted on the surface of the circuit board 300. The components such as the laser chip and the lens assembly are mounted in the transmitter shell. The laser chip receives an electrical signal from the circuit board 300 and converts the electrical signal into an optical signal. The optical signal is transmitted via the component such as the lens assembly to achieve optical signal transmission.

The optical receiver component 500 generally includes components such as a receiver shell, an optical receiver chip, and a transimpedance amplifier chip. The components such as the optical receiver chip and the transimpedance amplifier chip can be directly mounted on the surface of the circuit board 300. The receiver shell covers the components such as the optical receiver chip and the transimpedance amplifier chip. An optical fiber adapter transmits an external optical signal to the optical receiver chip via a receiving optical fiber. The optical receiver chip converts the external optical signal into an electrical signal. The electrical signal is amplified by the component such as the transimpedance amplifier chip and then transmitted to the circuit board 300. The electrical signal is transmitted to the host computer 100 via the gold finger to achieve optical signal reception.

FIG. 6 is a top view of a connection between a laser chip and a circuit board in an optical module according to some embodiments of the present disclosure.

Referring to FIG. 6, in some examples of the embodiment of the present disclosure, the circuit board 300 may be provided with a signal line.

In some examples, the circuit board 300 may be provided with a ground pad.

In some examples, the optical module may include a substrate 402. The substrate 402 may be provided with a ground metal region for a high-frequency transmission line.

In some examples, the high-frequency transmission line may be wire-bonded to the signal line.

In some examples, the ground metal region may be wire-bonded to the ground pad.

In some examples, the optical module may include a heater 404. The heater 404 may be mounted on the substrate 402.

In some examples, the heater 404 may be thermally isolated from the substrate 402. For example, a material with a low thermal conductivity is disposed between the heater and the substrate.

In some examples, the heater 404 may have a first power supply terminal. The first power supply terminal may be electrically connected to the circuit board 300. The first power supply terminal may be configured to transmit a driving current to the heater 404.

In some examples, the heater 404 may have a second power supply terminal. The second power supply terminal may be electrically connected to the circuit board 300. The second power supply terminal may be configured to power the heater 404.

In some examples, the heater 404 may have aground terminal. The ground terminal may be connected to the ground metal region.

In some examples, the laser chip 403 may be mounted on the ground metal region. The laser chip 403 may be located on one side of the heater 404. The laser chip 403 may be wire-bonded to the high-frequency transmission line.

In some examples, the heater 404 may be connected to the laser chip 403 via a gold wire. In some examples, the gold wire is configured to transmit the driving current and conduct heat to the laser chip, such that the laser chip generates an optical signal.

In some examples, the circuit board 300 may be provided with a laser bias circuit. One terminal of the laser bias circuit may be connected to the first power supply terminal. The laser bias circuit may be configured to output the driving current to the laser chip 403.

In some examples, the circuit board may be provided with a sampling resistor 305. The sampling resistor may be located between the laser bias circuit and the laser chip 403.

In some examples, the circuit board may be provided with an operational amplifier chip 306.

In some examples, the operational amplifier chip 306 may have a first input terminal. The first input terminal may be connected to a first terminal of the sampling resistor 305.

In some examples, the operational amplifier chip 306 may have a second input terminal. The second output terminal may be connected to a second terminal of the sampling resistor 305.

In some examples, the circuit board 300 may be provided with an MCU 302. The MCU 302 may be connected to an output terminal of the operational amplifier chip 306. The MCU 302 may be configured to receive a voltage difference of the sampling resistor 305 and convert the voltage difference into a bias current value for reading by the host computer.

In some examples, the MCU 302 may be connected to the laser bias circuit. The MCU 302 may be configured to control turn-on and turn-off of the laser bias circuit.

In some examples, the MCU 302 may be configured to control a magnitude of an output voltage of the laser bias circuit.

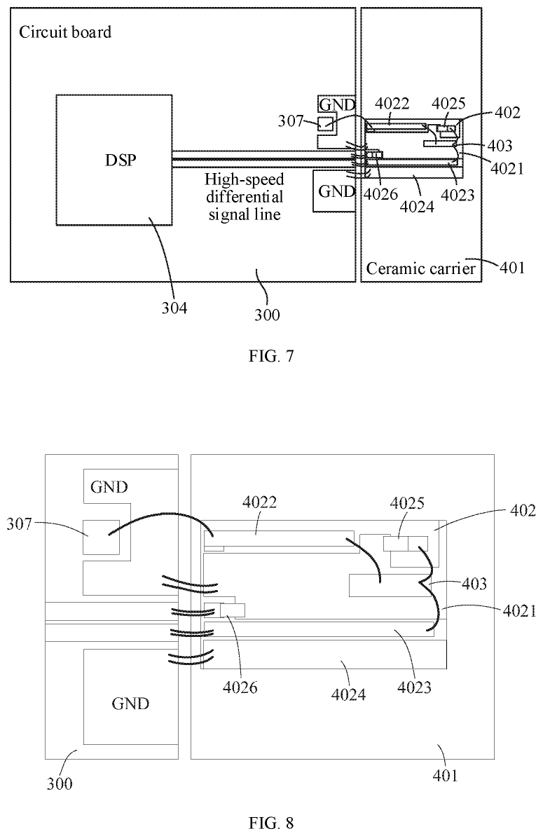

FIG. 7 is a top view of wire bonding of a laser in an optical module according to some embodiments of the present disclosure. FIG. 8 is a first partial enlarged view of wire bonding of a laser in an optical module according to some embodiments of the present disclosure. As shown in FIG. 7 and FIG. 8, for optical signal transmission, a DSP chip 304 is mounted on the surface of the circuit board 300. The DSP chip 304 is connected to the gold finger 301 via the signal line. The electrical signal provided by the host computer 100 is transmitted to the DSP chip 304 via the gold finger 301. The high-speed signal line is disposed on the surface of the circuit board 300, extends from the DSP chip 304 to the optical transmitter component 400, and transmits the high-frequency electrical signal output by the DSP chip 304 to the optical transmitter component 400, thereby driving the laser chip of the optical transmitter component 400 to generate an optical signal.

In some embodiments, to provide a flat optical bearing surface for the laser chip 403, the laser chip 403 is usually disposed on the substrate 402. A power supply transmission line is disposed on a surface of the substrate 402. The circuit board 300 is provided with a pad. One end of the power supply transmission line is electrically connected to the pad by wire bonding, and the other end of the power supply transmission line is electrically connected to a light-emitting region of the laser chip 403 by wire bonding. The bias current transmitted by the circuit board 300 is transmitted to the light-emitting region of the laser chip 403 via the power supply transmission line, thereby driving the laser chip 403 to generate a laser beam. In some embodiments, the substrate 402 may be a ceramic substrate.

The high-frequency transmission line 4023 is further disposed on the surface of the substrate 402. One end of the high-frequency transmission line 4023 is wire-bonded to the high-speed signal line to transmit the electrical signal transmitted by the signal line to the high-frequency transmission line 4023. The other end of the high-frequency transmission line 4023 is wire-bonded to the laser chip 403. The high-frequency electrical signal output by the DSP chip 304 is transmitted to the laser chip 403 via the high-frequency transmission line 4023, such that the laser chip 403 generates an optical signal.

To achieve signal return of the high-speed electrical signal, the circuit board 300 is further provided with a ground pad, and a first ground metal region 4021 is further formed on the surface of the substrate 402. The bottom surface of the laser chip 403 is mounted on the first ground metal region 4021. The power supply transmission line is not connected to the high-frequency transmission line 4023 and the first ground metal region 4021. The ground pad on the circuit board 300 is wire-bonded to the first ground metal region 4021, such that the first ground metal region 4021 on the substrate 402 is grounded.

In some embodiments, the substrate 402, the laser chip 403, and other components may be hermetically sealed during assembly. That is, the transmitter shell is a sealed shell, and the laser chip 403 is isolated from the external environment. When the optical module is in a low-temperature environment, external cold air will not enter the transmitter shell, such that no condensation will form on the laser chip 403 at low temperatures, thereby preventing the laser chip 403 from being damaged by condensation.

Alternatively, the substrate 402, the laser chip 403, and other components may be non-hermetically sealed during assembly. That is, the transmitter shell is a non-sealed shell, and the laser chip 403 is in communication with the external environment. When the optical module is in a low-temperature environment, external cold air will enter the transmitter shell, such that condensation may form on the laser chip 403 at low temperatures, thereby damaging the laser chip 403.

To prevent the condensation from easily forming on the laser chip 403 when the optical transmitter component 400 is non-hermetically sealed and the optical module is in the low-temperature environment, in the optical module provided by some embodiments of the present disclosure, a heater is additionally disposed on the substrate 402. The heater is located on one side of the laser chip. One end of the heater is electrically connected to the circuit board 300, and the other end of the heater is connected to the laser chip 403 via a gold wire. The heater generates heat under the current signal transmitted by the circuit board 300. The heat is conducted to a surface of the laser chip 403 via the gold wire to heat the surface of the laser chip 403, thereby preventing the condensation from forming on the laser chip 403 at low temperatures.

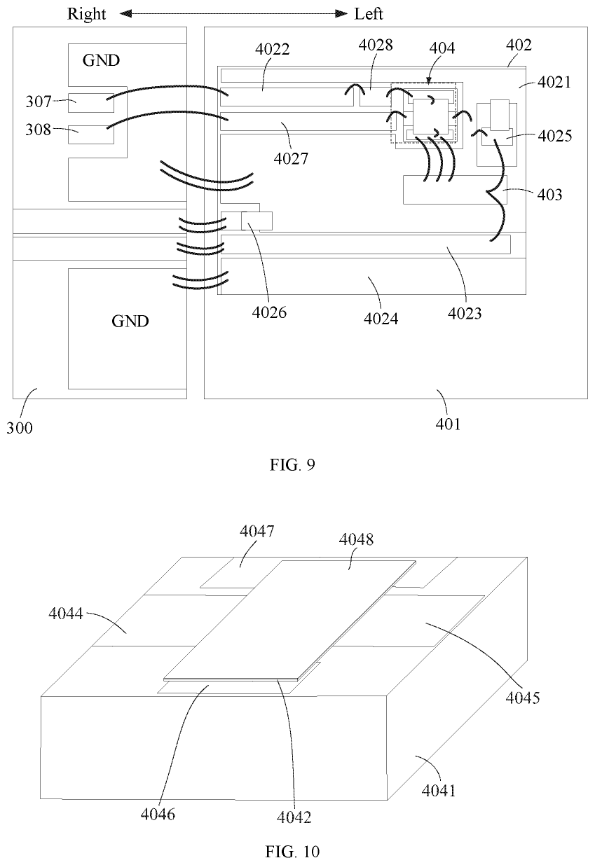

FIG. 9 is a second partial enlarged view of wire bonding of a laser in an optical module according to some embodiments of the present disclosure. As shown in FIG. 9, the circuit board 300 is provided with a signal line, a ground pad, a first pad 307, and a second pad 308. The ground pad may include a first ground pad and a second ground pad. The signal line is located between the first ground pad and the second ground pad to form a ground-signal-ground (GSG) structure.

The first pad 307 and the second pad 308 may be located on the upper side of the first ground pad. The first pad 307 is electrically connected to the light-emitting region of the laser chip 403 by wire bonding to provide a bias current to the laser chip 403. The second pad 308 is electrically connected to the heater by wire bonding to provide an operating current to the heater. In some examples, the operating current that enables the heater to operate and generate heat may also be referred to as a heating current.

In some embodiments, a notch may be formed in the first ground pad. The first pad 307 and the second pad 308 are located in the notch. The first pad 307 is electrically connected to the light-emitting region of the laser chip 403 by wire bonding to provide the bias current to the laser chip 403. The second pad 308 is electrically connected to the heater by wire bonding to provide the operating current to the heater.

By disposing the first pad 307 and the second pad 308 in the notch of the first ground pad, the wire bonding distance can be shortened, thereby reducing the power consumption of the optical module.

In some embodiments, to further shorten the wire bonding distance, the substrate 402 is further provided with a first power supply transmission line 4022 and a second power supply transmission line 4027. The first power supply transmission line 4022 and the second power supply transmission line 4027 extend from an edge of the substrate 402 toward the laser chip 403. The first power supply transmission line 4022 and the second power supply transmission line 4027 may be arranged side by side on the same side of the laser chip 403. Alternatively, the first power supply transmission line 4022 and the second power supply transmission line 4027 may be disposed on different sides of the laser chip 403. For example, the first power supply transmission line 4022 is located on the upper side of the laser chip 403, and the second power supply transmission line 4027 is located on the lower side of the laser chip 403.

One end of the first power supply transmission line 4022 is electrically connected to the first pad 307 by wire bonding, and the other end of the first power supply transmission line 4022 is electrically connected to the light-emitting region of the laser chip 403 by wire bonding, to transmit the bias current to the laser chip 403 via the first power supply transmission line 4022, thereby enabling the laser chip 403 to generate a laser beam.

One end of the second power supply transmission line 4027 is electrically connected to the first pad 308 by wire bonding, and the other end of the second power supply transmission line 4027 is electrically connected to the heater 404 on the substrate 402 by wire bonding, to transmit the operating current to the heater 404 via the second power supply transmission line 4027, thereby enabling the heater 404 to operate and generate heat.

In some embodiments, when the pads and a signal pad are arranged on the circuit board 300 in a GSG manner, the ground metal region on the substrate 402 includes a first ground metal region 4021 and a second ground metal region 4024. The high-frequency transmission line 4023 is located between the first ground metal region 4021 and the second ground metal region 4024. The first ground metal region 4021 is located at an upper portion of the substrate 402, and the second ground metal region 4024 is located at a lower portion of the substrate 402. The first ground metal region 4021 and the second ground metal region 4024 are not connected. The first ground pad is wire-bonded to the first ground metal region 4021, and the second ground pad is wire-bonded to the second ground metal region 4024.

To reduce wire bonding loss, the substrate 402 may be mounted on a carrier 401. The mounting height of the substrate 402 is elevated by the carrier 401, such that the wire bonding surface of the substrate 402 is flush with the surface of the circuit board 300, thereby reducing the wire bonding distance between the circuit board 300 and the substrate 402.

In some embodiments, the heater 404 may be embedded in a groove in the substrate 402, or the heater 404 may be mounted on the first ground metal region 4021 of the substrate 402. The heater 404 may be located between the second power supply transmission line 4027 and the left edge of the substrate 402, that is, the heater 404 is close to the left end of the second power supply transmission line 4027 (e.g., in the direction shown in FIG. 9), thereby shortening the wire bonding distance between the second power supply transmission line 4027 and the heater 404, and the wire bonding distance between the heater 404 and the laser chip 403.

The heater 404 generates heat under the operating current transmitted by the second power supply transmission line 4027. The gold wire serves as a thermal channel to conduct the heat to the laser chip 403, thereby heating the surface of the laser chip 403. In this way, when the optical module is in the low-temperature environment, the surface temperature of the laser chip 403 is relatively high, such that no condensation will form on the surface of the laser chip 403, thereby preventing damage to the laser chip 403 caused by condensation.

In some embodiments, when the heater 404 conducts heat to the laser chip 403 via the gold wire, the number of gold wires connecting the heater 404 to the laser chip 403 may be increased to raise the surface temperature of the laser chip 403. For example, two, three, or four gold wires may be used, such that the heat is conducted to the laser chip 403 via a plurality of thermal channels, thereby increasing the heat conduction rate and ensuring that no condensation forms on the surface of the laser chip 403.

In some embodiments, the heater 404 may be a heating resistor, which may include a single resistor or a plurality of resistors.

However, when the heater 404 is the heating resistor, since the heater 404 is mounted on the first ground metal region 4021 of the substrate 402, the heat generated by the heater 404 may be conducted to the first ground metal region 4021, resulting in less heat conducted by the gold wire. To ensure the surface temperature of the laser chip 403, the heater 404 is required to generate more heat, thereby increasing the power consumption of the optical module.

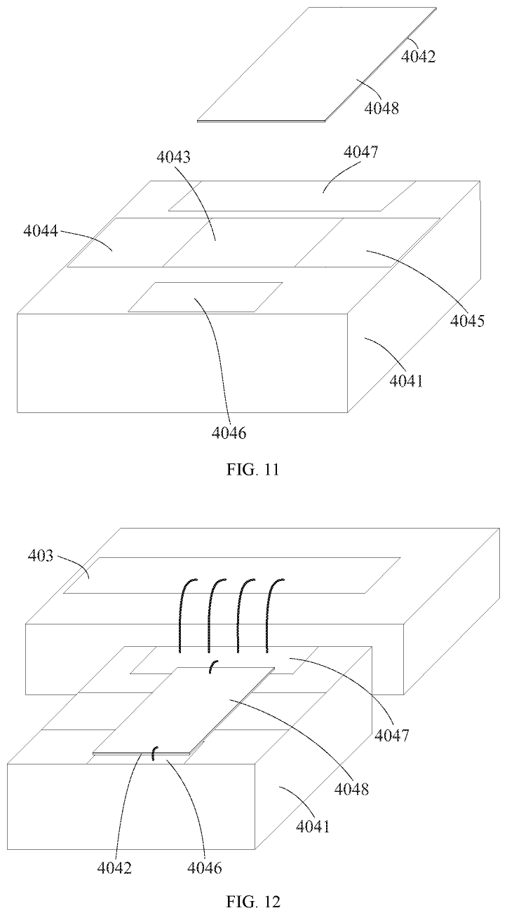

FIG. 10 is a structural diagram of a heater in an optical module according to some embodiments of the present disclosure. FIG. 11 is an exploded view of a heater in an optical module according to some embodiments of the present disclosure. As shown in FIG. 10 and FIG. 11, to reduce the power consumption of the optical module, the heater 404 may include a base 4041, a heating resistor 4043, and a thermally conductive plate 4042. The base 4041 is mounted on the first ground metal region 4021. The heating resistor 4043 is disposed on the base 4041. The heating resistor 4043 is electrically connected to the second power supply transmission line 4027 by wire bonding, such that the heating resistor 4043 is powered by the second power supply transmission line 4027, thereby enabling the heating resistor 4043 to operate and generate heat.

Since the thermal conductivity of the gold wire is 317 W/m-K, while that of quartz glass is very low at 1 W/m-K, to prevent the heat generated by the heating resistor 4043 from being conducted to the substrate 402 via the base 4041, the base 4041 may be a quartz base or a silicon dioxide base, that is, the base 4041 is thermally isolated from the substrate 402. In this way, the heat diffused from the heating resistor 4043 to the substrate 402 via the base 4041 is reduced, and most of the heat generated by the heating resistor 4043 is conducted to the laser chip 403 via the gold wire, thereby reducing the power consumption of the optical module.

In some embodiments, a first power supply pad 4044 (i.e., a second power supply terminal) and a ground pad 4045 (i.e., a ground terminal) are disposed on the top surface of the base 4041. The first power supply pad 4044 and the ground pad 4045 are located on both sides of the heating resistor 4043. The first power supply pad 4044 is located at one end of the base 4041 close to the second power supply transmission line 4027. The ground pad 4045 is located at one end of the base 4041 away from the second power supply transmission line 4027. The first power supply pad 4044 is electrically connected to the second power supply transmission line 4027 by wire bonding, and the ground pad 4045 is wire-bonded to the first ground metal region 4021, to power the heating resistor 4043 via the second power supply transmission line 4027, thereby driving the heating resistor 4043 to operate and generate heat.

Since the base 4041 has a low thermal conductivity, the thermally conductive plate 4042 covers the heating resistor 4043 to conduct the heat generated by the heating resistor 4043 to the laser chip 403. The thermally conductive plate 4042 is in contact with the heating resistor 4043, with high thermal conductivity and low electrical conductivity between the thermally conductive plate 4042 and the heating resistor 4043. That is, the thermally conductive plate 4042 is thermally conductive and electrically insulating, such that the heat from the heating resistor 4043 is conducted to the thermally conductive plate 4042, but the thermally conductive plate 4042 does not affect an electrical signal channel of the heating resistor 4043 at the bottom thereof.

In some embodiments, the thermally conductive plate 4042 may be an aluminum nitride ceramic plate. Aluminum nitride ceramic has a thermal conductivity of 160 W/m-K and is electrically insulating. Heat is conducted via the thermally conductive plate 4042 without affecting the electrical signal channel of the heating resistor 4043.

The thermally conductive plate 4042 may be connected to the laser chip 403 via a gold wire. The heat from the thermally conductive plate 4042 is conducted to the laser chip 403 via the gold wire, such that the heat generated by the heating resistor 4043 is conducted to the laser chip 403 with only low power consumption.

In some embodiments, the gold wire conducts heat to the laser chip 403, and the first power supply transmission line 4022 transmits the bias current to the laser chip 403 by wire bonding. The gold wire is a metal bonding wire and may serve as both a thermal channel and an electrical channel. Therefore, the gold wire may be used as both the thermal channel and the electrical channel to reduce loss. That is, the first power supply transmission line 4022 transmits the bias current to the thermally conductive plate 4042, such that the thermally conductive plate 4042 simultaneously transmits the current signal and the heat, which are then transmitted to the laser chip 403 via the gold wire.

Since the thermally conductive plate 4042 is thermally conductive and electrically insulating, a metal layer 4048 is plated on one side (the top surface) of the thermally conductive plate 4042 away from the base 4041 to enable the thermally conductive plate 4042 to transmit the current signal. The metal layer 4048 may occupy part of the top surface of the thermally conductive plate 4042 or cover the entire top surface of the thermally conductive plate 4042, but no metal layer is plated on the side surface and the bottom surface of the thermally conductive plate 4042.

After the metal layer 4048 is plated on the top surface of the thermally conductive plate 4042, one end of the metal layer 4048 is electrically connected to the first power supply transmission line 4022 by wire bonding, and the other end of the metal layer 4048 is connected to the laser chip 403 via a gold wire. The first power supply transmission line 4022 transmits the driving current to the metal layer 4048, and the metal layer 4048 transmits the driving current to the laser chip 403 via the gold wire, to drive the laser chip 403 to emit light. The heat generated by the heating resistor 4043 is conducted to the metal layer 4048 via the thermally conductive plate 4042, and the metal layer 4048 conducts the heat to the laser chip 403 via the gold wire, to heat the laser chip 403.

In this way, the gold wire serves as both the electrical channel and the thermal channel to transmit the driving current and the heat to the laser chip 403, thereby ensuring normal operation of the laser chip 403, and raising the surface temperature of the laser chip 403, such that no condensation will form on the laser chip 403 at low temperatures during normal operation.

Referring to FIG. 9, to facilitate wire bonding between the first power supply transmission line 4022 and the metal layer 4048, and between the metal layer 4048 and the laser chip 403, the first power supply transmission line 4022 is close to the upper edge of the substrate 402, the second power supply transmission line 4027 is located between the first power supply transmission line 4022 and the laser chip 403, the heater 404 is located on the upper side of the laser chip 403 and on the left side of the first power supply transmission line 4022 and the second power supply transmission line 4027, the heating resistor 4043 is disposed in the left-right direction, and the thermally conductive plate 4042 is disposed in the up-down direction.

FIG. 12 is a wire bonding diagram of a laser and a heater in an optical module according to some embodiments of the present disclosure. As shown in FIG. 12, to facilitate wire bonding between the metal layer 4048 and the first power supply transmission line 4022, and between the metal layer and the laser chip 403, a second power supply pad (i.e., a first power supply terminal) 4046 and a heat supply pad (i.e., a heat supply terminal) 4047 are further disposed on the top surface of the base 4041. The second power supply pad 4046 is located at one end of the base 4041 away from the laser chip 403. The heat supply pad 4047 is located at one end of the base 4041 close to the laser chip 403. The thermally conductive plate 4042 is pressed onto the second power supply pad 4046, the heating resistor 4043, and the heat supply pad 4047. The second power supply pad 4046 is electrically connected to the first power supply transmission line 4022 by wire bonding, the second power supply pad 4046 is electrically connected to the metal layer 4048 by wire bonding, the metal layer 4048 is electrically connected to the heat supply pad 4047 by wire bonding, and the heat supply pad 4047 is connected to the laser chip via a gold wire, thereby transmitting the driving current and conducting heat to the laser chip 403 via the heater 404.

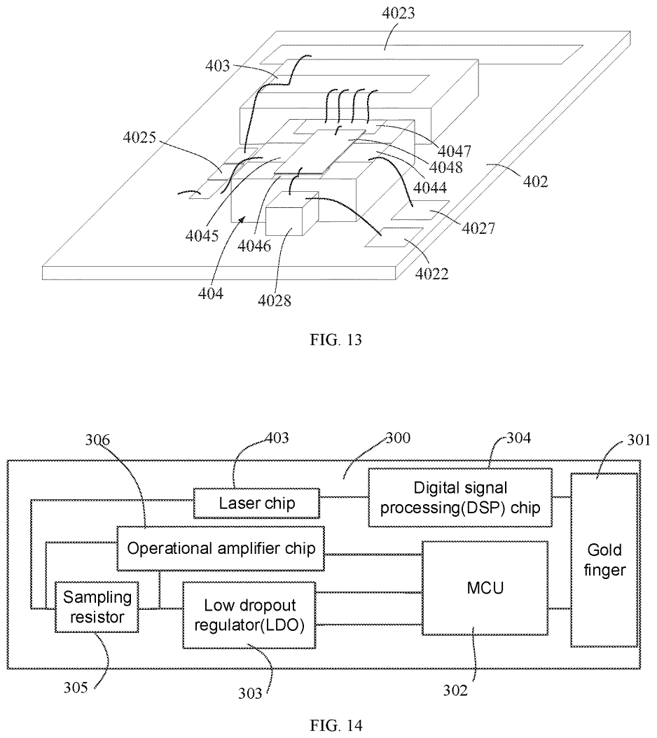

FIG. 13 is a schematic diagram of an electrical connection of a laser in an optical module according to some embodiments of the present disclosure. As shown in FIG. 9 and FIG. 13, the base 4041 is mounted on the first ground metal region 4021 of the substrate 402; then the thermally conductive plate 4042 is pressed onto the heating resistor 4043 on the base 4041; and then one end of the first power supply transmission line 4022 is electrically connected to the first pad 307 on the circuit board 300 by wire bonding, the other end of the first power supply transmission line 4022 is electrically connected to the second power supply pad 4046 by wire bonding, the second power supply pad 4046 is electrically connected to one end of the metal layer 4048 on the thermally conductive plate 4042 by wire bonding, the other end of the metal layer 4048 is electrically connected to the heat supply pad 4047 by wire bonding, and the heat supply pad 4047 is connected to the laser chip 403 via a plurality of gold wires, to transmit the driving current to the laser chip 403, thereby driving the laser chip 403 to generate a laser beam.

In some embodiments, there may be noise in the current signal transmitted by the first power supply transmission line 4022. To filter out this noise, the substrate 402 is further provided with a capacitor 4028. The capacitor 4028 is located on one side of the base 4041. One end of the first power supply transmission line 4022 is electrically connected to the capacitor 4028 by wire bonding, and the capacitor 4028 is electrically connected to the second power supply pad 4046 by wire bonding.

Then, the signal line on the circuit board 300 is wire-bonded to the high-frequency transmission line 4023 on the substrate 402, and the high-frequency transmission line 4023 is wire-bonded to the laser chip 403, to transmit the electrical signal output by the DSP chip to the laser chip 403, thereby enabling the laser chip 403 to generate an optical signal.

In some embodiments, when the optical transmitter component 400 transmits a signal, the signal line is wire-bonded to the high-frequency transmission line 4023, and the high-frequency transmission line 4023 is wire-bonded to the laser chip 403. The wire bonding has a certain characteristic impedance. When the output impedance of the laser chip 403 does not match the characteristic impedance of the high-frequency transmission line 4023, the signal transmitted between the laser chip 403 and the signal line may suffer loss, thereby reducing signal integrity. Therefore, to ensure the signal integrity, it is necessary to ensure that the output impedance of the laser chip 403 matches the characteristic impedance of the high-frequency transmission line 4023.

To match the output impedance of the laser chip 403 with the characteristic impedance of the high-frequency transmission line 4023, the substrate 402 is further provided with a first matching resistor 4025. Two pads are disposed on both sides of the first matching resistor 4025. The laser chip 403 is electrically connected to the pad on one side of the first matching resistor 4025 by wire bonding, and the pad on the other side of the first matching resistor 4025 is electrically connected to the first ground metal region 4021 by wire bonding, such that the first matching resistor 4025 and the laser chip 403 are connected in parallel in the circuit. In addition, the resistance value of the first matching resistor 4025 is equal to that of the high-frequency transmission line 4023, thereby achieving impedance matching between the laser chip 403 and the high-frequency transmission line 4023.

In some embodiments, the signal line on the circuit board 300 may be a differential signal line. When the differential signal line is wire-bonded to the high-frequency transmission line 4023, the substrate 402 is further provided with a second matching resistor 4026. Two pads are disposed on both sides of the second matching resistor. One differential signal line on the circuit board 300 is electrically connected to the pad on one side of the second matching resistor 4026 by wire bonding, and the pad on the other side of the second matching resistor 4026 is electrically connected to the first ground metal region 4021 by wire bonding, such that one differential signal line on the circuit board 300 is grounded, and the other differential signal line is wire-bonded to the high-frequency transmission line 4023. The resistance value of the second matching resistor 4026 is equal to that of the differential signal line, thereby achieving impedance matching between the differential signal line and the high-frequency transmission line 4023.

Then, one end of the second power supply transmission line 4027 is electrically connected to the first pad 308 on the circuit board 300 by wire bonding, the other end of the second power supply transmission line 4027 is electrically connected to the first power supply pad 4044 by wire bonding, and the ground pad 4045 is wire-bonded to the first ground metal region 4021, to transmit the heating current to the heating resistor 4043, thereby enabling the heating resistor 4043 to operate and generate heat. The heat is conducted to the metal layer 4048 on the top surface of the thermally conductive plate 4042, and the metal layer 4048 conducts the heat to the laser chip 403 via the gold wire, to heat the laser chip 403, thereby preventing condensation from forming on the surface of the laser chip 403 at low temperatures.

In some embodiments, the laser chip 403 may be an electroabsorption modulated laser (EML). The heat supply pad 4047 of the heater 404 is connected to the light-emitting region of the EML laser chip via a gold wire to enable the EML laser chip to emit light. The high-frequency transmission line 4023 on the substrate 402 is connected to a modulation region of the EML laser chip. The modulation region modulates the electrical signal onto the laser beam generated by the laser chip to generate a modulated optical signal.

In some embodiments, the heating resistor 4043 in the heater 404 may heat or stop heating according to actual conditions. For example, when the temperature of the laser chip 403 is lower than a certain temperature, the heating resistor 4043 starts to operate and generates heat, which is conducted to the laser chip 403 via the gold wire to prevent condensation from forming on the surface of the laser chip 403. When the temperature of the laser chip 403 is higher than a certain temperature, the heating resistor 4043 stops operating to reduce the power consumption of the optical module.

To control start and stop of the heating resistor 4043, the optical module provided by the embodiment of the present disclosure further includes a temperature sensor and an MCU. The temperature sensor may be mounted on the substrate 402. The MCU is mounted on the circuit board 300 and connected to the temperature sensor. The temperature sensor is configured to detect a temperature of the laser chip 403. The temperature sensor transmits the detected temperature to the MCU, and the MCU controls connection and disconnection between the heating resistor 4043 and the circuit board 300 based on the detected temperature to control the start and stop of the heating resistor 4043.

In some embodiments, the temperature sensor may also be integrated into the MCU.

When the temperature detected by the temperature sensor is lower than a preset temperature, the MCU controls the first power supply pad 4044 of the heater 404 to be wire-bonded to the circuit board 300. The circuit board 300 supplies power to the heating resistor 4043 via the first power supply pad 4044, thereby enabling the heating resistor 4043 to operate and generate heat. The heat is conducted to the laser chip 403 via the gold wire to heat the laser chip 403, thereby preventing condensation from forming on the surface of the laser chip 403 at low temperatures.

When the temperature detected by the temperature sensor is higher than the preset temperature, the MCU controls the first power supply pad 4044 of the heater 404 to be disconnected from a wire-bonded connection to the circuit board 300, such that a power supply current of the circuit board 300 cannot be transmitted to the heating resistor 4043, thereby enabling the heating resistor 4043 to stop heating. The gold wire connecting the laser chip 403 to the heat supply pad 4047 only transmits the driving current signal, thereby enabling the laser chip 403 to generate a laser beam.

In some embodiments, the preset temperature for the MCU to control the start and stop of the heating resistor 4043 may be 10° C.

In some embodiments, the structure of the heater 404 is not limited to the above structure. As long as the heater 404 can transmit the driving current and conduct heat to the laser chip 403, it falls within the scope of protection of the embodiment of the present disclosure.

In the optical module provided by the present disclosure, the heater is additionally disposed on one side of the laser chip. The heater is composed of the base, the heating resistor, and the thermally conductive plate. The base is mounted on the substrate. The heating resistor is disposed on the top surface of the base. The thermally conductive plate is pressed onto the heating resistor. The metal layer is plated on the top surface of the thermally conductive plate. The driving current transmitted by the circuit board is transmitted to the metal layer, and the driving current from the metal layer is transmitted to the light-emitting region of the laser chip via the gold wire, thereby enabling the laser chip to generate a laser beam. The heating resistor generates heat under the action of the current signal transmitted by the circuit board, and the heat is transmitted to the thermally conductive plate. The thermally conductive plate conducts the heat to the laser chip via the gold wire. In this way, the gold wire serves as both the electrical channel and the thermal channel to transmit the driving current and the heat to the laser chip, thereby raising the surface temperature of the laser chip. This prevents condensation from forming on the laser chip at low temperatures during normal operation, such that low-temperature condensation on the laser chip is avoided under low power consumption.

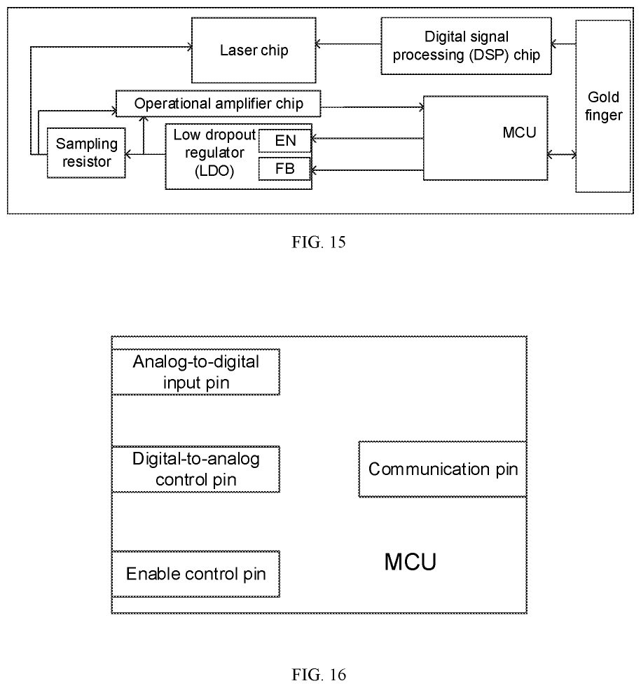

FIG. 14 is a schematic diagram of a partial structure of an optical module according to some embodiments of the present disclosure. FIG. 15 is a schematic diagram of a partial signal flow of an optical module according to some embodiments of the present disclosure. Referring to FIG. 14 and FIG. 15, some embodiments of the present disclosure provide an optical module, where one terminal of the circuit board is provided with a gold finger, connected to the host computer, and configured to receive an electrical signal from the host computer. The MCU 302 is disposed on the circuit board and connected to the gold finger 301, receives an electrical signal from the host computer and processes the same, and is configured to control the laser bias circuit.

In some examples, the laser bias circuit may include a low dropout regulator (LDO).

In some examples, the LDO is connected to the MCU 302 and receives a control signal from the MCU 302. The MCU 302 outputs a signal to the LDO to control turn-on and turn-off of the LDO. The LDO is connected to the laser chip 403 and outputs a bias signal to drive the laser chip 403.

In some examples, the LDO may be electrically connected via the first power supply transmission line described in the foregoing embodiment of the present disclosure to provide the driving current to the laser chip 403 via the heater.

The DSP chip 304 is electrically connected to the gold finger, receives a control signal from the host computer, is connected to the laser chip 403, and outputs a modulated signal to the laser chip 403.

One terminal of the LDO is connected to the laser chip and configured to output a direct-current drive signal to an optical transmitter chip. One terminal of the DSP chip is connected to the laser chip and configured to output an alternating-current load signal to the optical transmitter chip.

The LDO 303 receives the control signal from the MCU 302 and outputs the bias signal to the laser chip to drive the laser chip 403. The DSP chip outputs the modulated signal to the laser chip 403 to perform amplitude modulation on the laser chip 403. There is no complex, integrated, and expensive driver chip for the optical transmitter chip in the present disclosure. The laser chip 403 is directly driven by the LDO. By replacing the integrated driver chip for the optical transmitter chip with the independently designed LDO, the circuit design is simplified, the module cost is reduced, and the dependence on the driver chip for the optical transmitter chip is eliminated.

In some embodiments, the circuit board is further provided with a sampling resistor 305 and an operational amplifier chip 306. The sampling resistor is disposed between the LDO and the laser chip, and collects the magnitude of the bias current flowing from the LDO to the optical transmitter chip. A first input terminal of the operational amplifier chip 306 is connected to a first terminal of the sampling resistor, a second input terminal of the operational amplifier chip 306 is connected to a second terminal of the sampling resistor, and an output terminal of the operational amplifier chip 306 is connected to the MCU. The operational amplifier chip 306 collects an analog voltage difference between both ends of the sampling resistor and transmits the analog voltage difference to the MCU. The MCU receives the analog voltage difference and converts it into a bias current value. The host computer is communicatively connected to the MCU via the gold finger, reads the bias current value in the MCU, and completes reporting of the bias current value.

In some embodiments, the gold finger is connected to the MCU via an IIC communication bus, thereby achieving a communication connection between the gold finger and the MCU.

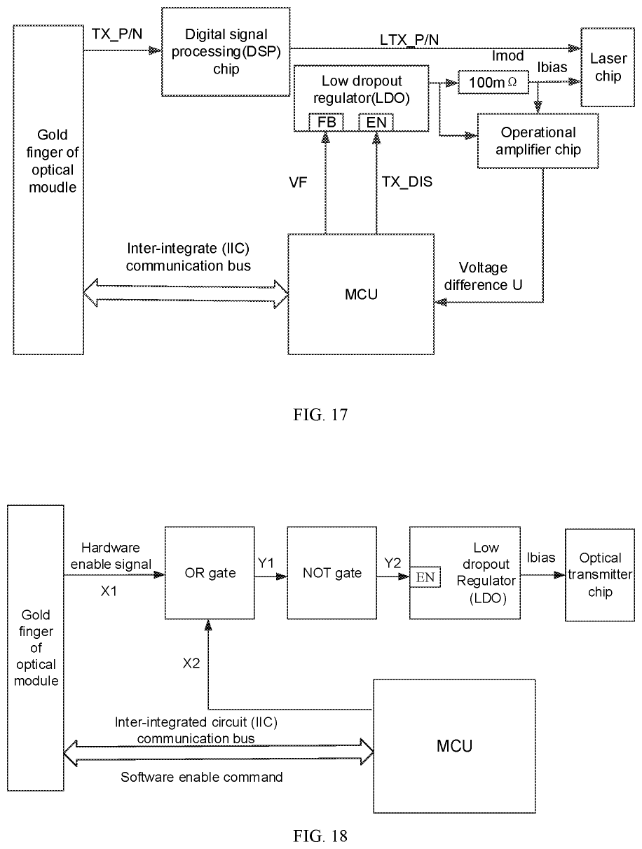

FIG. 16 is a schematic structural diagram of an MCU according to some embodiments of the present disclosure. FIG. 17 is a schematic diagram of a signal flow in an optical module according to some embodiments of the present disclosure. As shown in FIG. 16 and FIG. 17, the MCU has an enable control pin connected to an enable (EN) pin of the LDO. The MCU controls turn-on and turn-off of the LDO via the enable control pin.

In some examples, the enable control pin is a general-purpose input/output (GPIO) port. When a signal output from the enable control pin is at a high voltage, the LDO is turned on. When the signal output from the enable control pin is at a low voltage, the LDO is turned off.

The MCU has a digital-to-analog control pin connected to a feedback (FB) regulation pin of the LDO. The MCU outputs a signal via the digital-to-analog control pin to control the FB regulation pin, thereby controlling a magnitude of an output current of the LDO.

The LDO is disposed on the circuit board. The FB regulation pin and the EN pin of the LDO are connected to the MCU 302, and the output terminal of the LDO is connected to the laser chip, to directly drive the laser chip 403, thereby reducing configuration of a commonly used laser driver chip and a related matching circuit of the laser driver chip, which is beneficial to reducing the occupied area of the circuit board and improving the integration level of the module.

In the embodiment of the present disclosure, the LDO is controlled by the MCU to output different bias currents to drive the laser chip, thereby keeping the laser chip turned on and operating stably.

In some embodiments, the sampling resistor is 100 mΩ.

In some embodiments, the alternating-current load signal output by the DSP chip and the drive signal output by the LDO are jointly applied to the laser chip.

To further reduce signal disturbance, a first filter network is disposed at the output terminal of the LDO to prevent the alternating-current signal from passing in the reverse direction. The first filter network is an RL filter network, which is mainly an alternating-current filter network constructed by a resistor and an inductor or a magnetic bead. Its main function is to allow the direct-current bias current to pass in the forward direction and prevent the alternating-current signal from passing in the reverse direction and interfering with normal operation of the direct-current signal.

A sampling resistor 305 and an operational amplifier chip 306 are disposed between the LDO and the laser chip. The sampling resistor is disposed between the LDO and the laser chip, and collects the magnitude of the bias current flowing from the LDO to the laser chip. A first input terminal of the operational amplifier chip 306 is connected to a first terminal of the sampling resistor, a second input terminal of the operational amplifier chip 306 is connected to a second terminal of the sampling resistor, and an output terminal of the operational amplifier chip 306 is connected to the MCU. The operational amplifier chip 306 collects an analog voltage difference between both ends of the sampling resistor and transmits the analog voltage difference to the MCU. The MCU receives the analog voltage difference and converts it into a bias current value. The host computer is communicatively connected to the MCU via the gold finger, reads the bias current value in the MCU, and completes reporting of the bias current value.

In some embodiments of the present disclosure, the LDO is connected to the MCU. The EN pin of the LDO is used to control turn-on and turn-off of the laser chip. The digital-to-analog control pin of the MCU is used to control the FB regulation pin of the LDO to regulate the output voltage of the LDO, thereby implementing the regulation function of the bias current of the laser. By using the sampling resistor in combination with the operational amplifier chip, the bias current of the laser chip is collected, thereby implementing the monitoring and reporting function of the bias current of the laser chip.

In some embodiments of the present disclosure, a direct current-direct current (DCDC) power chip may also be provided to replace the LDO. The DCDC chip is a laser bias circuit. The MCU is provided with an enable pin, which is connected to the DCDC chip and configured to achieve turn-on and turn-off of the DCDC chip. The DCDC chip is also connected to a power circuit, which provides an input voltage for the DCDC chip.

In some embodiments of the present disclosure, a circuit such as a current digital-to-analog converter (IDAC) chip or an operational amplifier may also be used. The IDAC chip or the operational amplifier serves as a laser bias circuit and is configured to be connected to the control pin of the MCU and to output different driving voltages to the laser chip according to a magnitude of a control voltage of the MCU.

In some embodiments, the optical module is further provided with a temperature detector, which is configured to detect an ambient temperature of the laser chip and control the magnitude of the control voltage output to the LDO based on the ambient temperature of the laser chip. The MCU has a built-in temperature-voltage relationship algorithm, and calculates the magnitude of the output voltage based on the received temperature.

In the circuit that uses the laser driver chip to drive the laser chip, a hardware enable signal sent by the host computer is directly connected to the laser driver chip to achieve on/off control of the laser chip by the host computer. The hardware enable signal is also sent to the MCU to monitor its state. The host computer sends a software enable signal to the MCU of the optical module via the IIC bus. After receiving a software enable signal command, the MCU sends an on/off command to the laser driver chip via the IIC bus therebetween, thereby implementing the software enable function of the optical module.

In some embodiments, the optical module includes an MCU, a logic circuit, an LDO, and a laser chip. The MCU is communicatively connected to the gold finger and receives a software enable control command from the host computer. An enable control pin of the MCU is connected to a first input terminal of the logic circuit, and a second input terminal of the logic circuit is connected to the gold finger. An output terminal of the logic circuit is connected to the EN pin of the LDO. The hardware enable signal of the host computer serves as a first input signal of the logic circuit, and the software enable signal of the optical module serves as a second input signal of the logic circuit. An output signal of the logic circuit is connected to the EN pin of the LDO and configured to control turn-on and turn-off of the LDO, thereby achieving complete hardware and software enable control of the turn-on and turn-off of the laser chip by the host computer. In a control circuit provided by the present disclosure, when both the hardware enable signal sent from the gold finger to the logic circuit and the software enable signal sent from the MCU to the logic circuit are at a low level, the output of the logic circuit is at a high level, thereby controlling the laser chip to emit light.

In some embodiments, the logic circuit includes an OR gate logic circuit and a NOT gate logic circuit.

FIG. 18 is a second schematic structural diagram of an optical module according to some embodiments of the present disclosure. For an optical module without a laser driver chip, to achieve on/off control of the laser chip by the host computer, as shown in FIG. 18, the circuit board is provided with an OR gate logic circuit and a NOT gate logic circuit. The enable control pin of the MCU is connected to a first input terminal of the OR gate logic circuit, and the second input terminal of the OR gate logic circuit is connected to the gold finger. An output terminal of the OR gate logic circuit is connected to an input terminal of the NOT gate logic circuit. An output terminal of the NOT gate logic circuit is connected to the EN pin of the LDO. The hardware enable signal of the host computer serves as an input signal X1 of an OR gate, and the software enable signal of the optical module serves as an input signal X2 of the OR gate. An output signal Y1 of the OR gate serves as an input signal of a NOT gate, and an output signal Y2 of the NOT gate is connected to the EN pin of the LDO, which is configured to control turn-on and turn-off of the LDO, thereby achieving complete hardware and software enable control of the turn-on and turn-off of the laser chip by the host computer.

Table 1 is a control logic table provided according to the structure shown in FIG. 18. As shown in Table 1, when both the hardware enable signal sent from the gold finger to the OR gate logic circuit and the software enable signal sent from the MCU to the OR gate logic circuit are at a low level, the output of the OR gate logic circuit is at a low level, and the output of the NOT gate logic circuit is at a high level, thereby controlling the laser chip to emit light.

When the hardware enable signal sent from the gold finger to the OR gate logic circuit is at a low level and the software enable signal sent from the MCU to the OR gate logic circuit is at a high level, the output of the OR gate logic circuit is at a high level, and the output of the NOT gate logic circuit is at a low level, thereby controlling the laser chip not to emit light.

When the hardware enable signal sent from the gold finger to the OR gate logic circuit is at a high level and the software enable signal sent from the MCU to the OR gate logic circuit is at a low level, the output of the OR gate logic circuit is at a high level, and the output of the NOT gate logic circuit is at a low level, thereby controlling the laser chip not to emit light.

When both the hardware enable signal sent from the gold finger to the OR gate logic circuit and the software enable signal sent from the MCU to the OR gate logic circuit are at a high level, the output of the OR gate logic circuit is at a high level, and the output of the NOT gate logic circuit is at a low level, thereby controlling the laser chip not to emit light.

The optical module provided by the present disclosure includes an MCU, an OR gate logic circuit, a NOT gate logic circuit, an LDO, and a laser chip. The MCU is communicatively connected to the gold finger and receives a software enable control command from the host computer. An enable control pin of the MCU is connected to a first input terminal of the OR gate logic circuit, and a second input terminal of the OR gate logic circuit is connected to the gold finger. An output terminal of the OR gate logic circuit is connected to an input terminal of the NOT gate logic circuit. An output terminal of the NOT gate logic circuit is connected to the EN pin of the LDO. The hardware enable signal of the host computer serves as an input signal of an OR gate, and the software enable signal of the optical module serves as an input signal of the OR gate. An output signal of the OR gate serves as an input signal of a NOT gate, and an output signal of the NOT gate is connected to the EN pin of the LDO, which is configured to control turn-on and turn-off of the LDO, thereby achieving complete hardware and software enable control of the turn-on and turn-off of the laser chip by the host computer. In the control circuit provided by the present disclosure, when both the hardware enable signal sent from the gold finger to the OR gate logic circuit and the software enable signal sent from the MCU to the OR gate logic circuit are at a low level, the output of the OR gate logic circuit is at a low level, and the output of the NOT gate logic circuit is at a high level, thereby controlling the laser chip to emit light.

TABLE 1
Control logic table

| Hardware | Software | output | output Y2 | EN pin | Optical |
|---|---|---|---|---|---|
| enable | enable | Y1 of | of NOT | state of | transmitter |
| signal X1 | signal X2 | OR gate | gate | LDO | chip |
| Low | Low | Low | High | High | Light |
| | | | | | emission |
| Low | High | High | Low | Low | No light |
| | | | | | emission |
| High | Low | High | Low | Low | No light |
| | | | | | emission |
| High | High | High | Low | Low | No light |
| | | | | | emission |

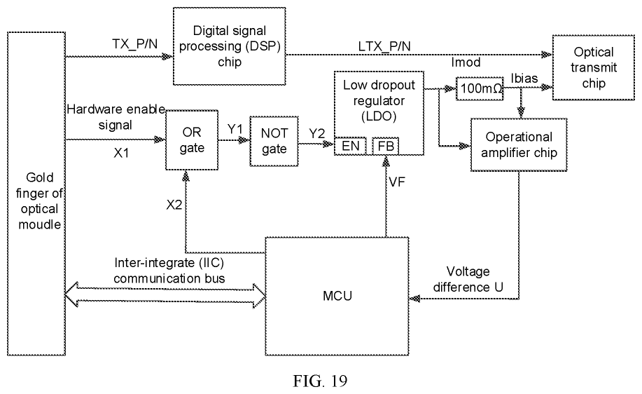

FIG. 19 is a third schematic structural diagram of an optical module according to some embodiments of the present disclosure. As shown in FIG. 19, the optical module is provided with an MCU, a DSP chip, an LDO, and a laser chip. The MCU has an enable control pin. The enable control pin is connected to the first input terminal of the OR gate logic circuit, and the second input terminal of the OR gate logic circuit is connected to the gold finger. The output terminal of the OR gate logic circuit is connected to the input terminal of the NOT gate logic circuit. The output terminal of the NOT gate logic circuit is connected to the EN pin of the LDO, which is configured to control turn-on and turn-off of the LDO, thereby achieving complete hardware and software enable control of the turn-on and turn-off of the laser chip by the host computer. In the control circuit provided by the present disclosure, when both the hardware enable signal sent from the gold finger to the OR gate logic circuit and the software enable signal sent from the MCU to the OR gate logic circuit are at a low level, the output of the OR gate logic circuit is at a low level, the output of the NOT gate logic circuit is at a high level, and the bias signal is output, thereby controlling the laser chip to emit light.

The MCU has a digital-to-analog control pin connected to the FB regulation pin of the LDO. The MCU outputs a signal via the digital-to-analog control pin to control the FB regulation pin, thereby controlling the magnitude of the output current of the LDO. The DSP chip is electrically connected to the gold finger, receives the control signal from the host computer, is connected to the laser chip, and outputs the modulated signal to the laser chip, thereby achieving signal modulation of the light emitted by the laser chip. There is no complex, integrated, and expensive driver chip for the laser chip in the present disclosure. The laser chip 403 is directly driven by the LDO. On the basis of the hardware of the existing optical module, the integrated driver chip for the laser chip is replaced with the independently designed LDO, such that the circuit design is simplified, the module cost is reduced, and the dependence on the driver chip for the laser chip is eliminated. In addition, the simple OR gate logic circuit and NOT gate logic circuit are combined with the MCU to achieve complete hardware and software enable control of the turn-on and turn-off of the laser chip by the host computer.

In some embodiments, a sampling resistor and an operational amplifier chip are disposed between the LDO and the laser chip. The sampling resistor is disposed between the LDO and the laser chip, and collects the magnitude of the bias current flowing from the LDO to the laser chip. A first input terminal of the operational amplifier chip is connected to a first terminal of the sampling resistor, a second input terminal of the operational amplifier chip is connected to a second terminal of the sampling resistor, and an output terminal of the operational amplifier chip is connected to the MCU. The operational amplifier chip collects an analog voltage difference between both ends of the sampling resistor and transmits the analog voltage difference to the MCU. The MCU receives the analog voltage difference and converts it into a bias current value. The host computer is communicatively connected to the MCU via the gold finger, reads the bias current value in the MCU, and completes reporting of the bias current value.

Finally, it should be noted that the above embodiments are provided merely to illustrate the technical solutions of the present disclosure and not to limit them. Although the present disclosure has been described in detail with reference to the aforementioned embodiments, those of ordinary skill in the art should understand that they can still make modifications on the technical solutions described in the aforementioned embodiments or make equivalent replacements on some of the technical features; and these modifications or replacements do not make the essence of the corresponding technical solutions depart from the spirit and scope of the technical solutions of the various embodiments of the present disclosure.

What is claimed is:

1. An optical module, comprising:
a circuit board, provided with a signal line, a first pad, a second pad, and a ground pad;
a substrate, provided with a high-frequency transmission line and a ground metal region, wherein the high-frequency transmission line is wire-bonded to the signal line, and the ground metal region is wire-bonded to the ground pad;
a heater, mounted on the substrate, wherein the heater is thermally isolated from the substrate, the heater comprises a heating resistor and a thermally conductive plate, the heating resistor is configured to generate heat, the thermally conductive plate covers the heating resistor, one side of the thermally conductive plate in contact with the heating resistor is insulated, and one side of the thermally conductive plate away from the heating resistor is plated with a metal layer;
a laser chip, mounted on the ground metal region, wherein the heater is located on one side of the laser chip, and the laser chip is wire-bonded to the high-frequency transmission line and configured to generate an optical signal; and
a first matching resistor, disposed on the substrate, wherein one terminal of the first matching resistor is wire-bonded to the laser chip, and the other terminal thereof is wire-bonded to the ground metal region, to achieve impedance matching between the laser chip and the high-frequency transmission line;
wherein
the substrate is further provided with a first power supply transmission line and a second power supply transmission line;
the second power supply transmission line electrically connects the second pad to the heating resistor to transmit a heating current output from the second pad to the heating resistor, thereby enabling the heating resistor to operate and generate heat; and
the first power supply transmission line electrically connects the first pad to the metal layer, and the metal layer is connected to the laser chip via a gold wire, to transmit a driving current output from the first pad to the laser chip and conduct the heat generated by the heating resistor to the laser chip.

2. The optical module according to claim 1, wherein the heater further comprises:
a base, mounted on the substrate, wherein a thermal conductivity between the base and the substrate is lower than a thermal conductivity between the gold wire and the laser chip;
a second power supply terminal, disposed at one end of the base close to the second power supply transmission line and wire-bonded to the second power supply transmission line; and
a ground terminal, disposed at one end of the base away from the second power supply transmission line and wire-bonded to the ground metal region,
wherein the heating resistor is disposed on the base, and has one terminal electrically connected to the second power supply terminal and the other terminal electrically connected to the ground terminal; and
a thermal conductivity between the thermally conductive plate and the heating resistor is higher than a thermal conductivity between the heating resistor and the base, one end of the metal layer is wire-bonded and electrically connected to a first power supply terminal, the other end of the metal layer is connected to the laser chip via a gold wire, and the thermally conductive plate is configured to transmit the driving current and conduct heat.

3. The optical module according to claim 2, wherein the heater further comprises:
the first power supply terminal, disposed at one end of the base close to the laser chip and wire-bonded to the first power supply transmission line; and
a heat supply terminal, disposed at one end of the base away from the laser chip,
wherein the thermally conductive plate covers the first power supply terminal, the heating resistor, and the heat supply terminal, one end of the metal layer is wire-bonded to the first power supply terminal, the other end thereof is wire-bonded to the heat supply terminal, and the heat supply terminal is connected to the laser chip via a gold wire.

4. The optical module according to claim 2, wherein the base is a quartz base, and the thermally conductive plate is an aluminum nitride ceramic plate.

5. The optical module according to claim 3, wherein the circuit board is provided with:
a laser bias circuit, connected at one terminal to the first power supply terminal and configured to output the driving current to the laser chip;
a sampling resistor, located between the laser bias circuit and the laser chip;
an operational amplifier chip, having a first input terminal connected to a first terminal of the sampling resistor and a second input terminal connected to a second terminal of the sampling resistor; and
a microcontroller unit (MCU), connected to an output terminal of the operational amplifier chip and configured to receive a voltage difference of the sampling resistor and convert the voltage difference into a bias current value for reading by a host computer,
wherein the MCU is further connected to the laser bias circuit, and the MCU controls turn-on and turn-off of the laser bias circuit and controls a magnitude of an output voltage of the laser bias circuit.

6. The optical module according to claim 5, further comprising:
a temperature sensor, mounted on the substrate and configured to detect a temperature of the laser chip,
wherein the MCU is connected to the temperature sensor, and the MCU is configured to control connection or disconnection between the second power supply terminal and the circuit board based on the detected temperature.

7. The optical module according to claim 6, wherein when the detected temperature is lower than a preset temperature, the MCU controls the second power supply terminal to be wire-bonded to the circuit board, such that the heater operates to generate heat; and
when the detected temperature is higher than the preset temperature, the MCU controls the second power supply terminal to be disconnected from a wire-bonded connection to the circuit board, such that the heater stops heating.

8. The optical module according to claim 1, further comprising a second matching resistor,
wherein the signal line on the circuit board is a differential signal line, one differential signal line is electrically connected to the second matching resistor by wire bonding, and the other differential signal line is wire-bonded to the high-frequency transmission line;
the second matching resistor is electrically connected to the ground metal region by wire bonding, such that one differential signal line on the circuit board is grounded; and the second matching resistor is configured to achieve impedance matching between the differential signal line and the high-frequency transmission line.

9. The optical module according to claim 3, further comprising a capacitor,
wherein the capacitor is disposed on one side of the heater, and has one terminal electrically connected to the first power supply transmission line by wire bonding and the other terminal electrically connected to the first power supply terminal.

10. The optical module according to claim 5, wherein the laser bias circuit comprises a low dropout regulator (LDO); and
the MCU is provided with:
an enable control pin, connected to an enable (EN) pin of the LDO and configured to control turn-on and turn-off of the LDO;
a digital-to-analog control pin, connected to a feedback (FB) regulation pin of the LDO and configured to control an output voltage of the LDO; and
an analog-to-digital input pin, connected to the output terminal of the operational amplifier chip and configured to receive the voltage difference and convert the voltage difference into the bias current value for reading by the host computer.

11. The optical module according to claim 10, wherein the circuit board is further provided with a digital signal processing (DSP) chip that has one terminal connected to the laser chip and outputs an alternating-current load signal to the laser chip.

12. The optical module according to claim 11, wherein the circuit board is further provided with a first filter network located between an output terminal of the laser bias circuit and the laser chip and configured to prevent the alternating-current load signal from passing in a reverse direction.

13. The optical module according to claim 5, further comprising:
an upper shell; and
a lower shell, covering the upper shell to form a cavity,
wherein the circuit board is disposed inside the cavity and provided with a gold finger;
the MCU is connected to the gold finger; and
the circuit board is further provided with a logic circuit, wherein a first input terminal of the logic circuit is connected to the gold finger and configured to receive a hardware enable signal from the gold finger; a second input terminal of the logic circuit is connected to the MCU and configured to receive a software enable signal from the MCU; an output terminal of the logic circuit is connected to the laser bias circuit; and
the logic circuit is configured to control the laser bias circuit to operate when both the hardware enable signal and the software enable signal are at a low level, and to turn off the laser bias circuit in other cases.

14. The optical module according to claim 13, wherein the logic circuit comprises:
an OR gate logic circuit, a first input terminal thereof being connected to the gold finger and configured to receive the hardware enable signal from the gold finger, and a second input terminal thereof being connected to the MCU and configured to receive the software enable signal from the MCU; and
a NOT gate logic circuit, having an input terminal connected to an output terminal of the OR gate logic circuit and an output terminal connected to the laser bias circuit,
wherein the OR gate logic circuit is configured such that the output terminal thereof outputs a low level when at least one of signals input to the first input terminal and the second input terminal thereof is at a high level; and
the NOT gate logic circuit is configured such that a signal output from the output terminal thereof is at a high level when a signal input to the input terminal thereof is at a low level, or the signal output from the output terminal thereof is at a low level when the signal input to the input terminal thereof is at a high level.

15. The optical module according to claim 14, wherein
the laser bias circuit comprises an LDO connected at one terminal to the first power supply terminal and configured to output a direct-current drive signal to the laser chip;
the MCU is connected to the gold finger; and
the circuit board is provided with:
the gold finger; and
the logic circuit, wherein the first input terminal of the logic circuit is connected to the gold finger and configured to receive the hardware enable signal from the gold finger; the second input terminal of the logic circuit is connected to the MCU and configured to receive the software enable signal from the MCU; the output terminal of the logic circuit is connected to the LDO; and
the logic circuit is configured to control the LDO to operate when both the hardware enable signal and the software enable signal are at the low level, and to turn off the LDO in other cases.

16. The optical module according to claim 15, wherein the logic circuit comprises:
the OR gate logic circuit, the first input terminal thereof being connected to the gold finger and configured to receive the hardware enable signal from the gold finger, and the second input terminal thereof being connected to the MCU and configured to receive the software enable signal from the MCU; and
the NOT gate logic circuit, having the input terminal connected to the output terminal of the OR gate logic circuit and the output terminal connected to the LDO,
wherein the OR gate logic circuit is configured such that the output terminal thereof outputs the low level when at least one of the signals input to the first input terminal and the second input terminal thereof is at the high level; and
the NOT gate logic circuit is configured such that the signal output from the output terminal thereof is at the high level when the signal input to the input terminal thereof is at the low level, and the signal output from the output terminal thereof is at the low level when the signal input to the input terminal thereof is at the high level.

17. The optical module according to claim 15, wherein the MCU is provided with:
an enable control pin, connected to the second input terminal of the logic circuit and configured to output the software enable signal to the second input terminal of the logic circuit; and
a digital-to-analog control pin, connected to an FB regulation pin of the LDO and configured to control an output voltage of the LDO.

18. The optical module according to claim 2, wherein
the ground pad of the circuit board comprises a first ground pad and a second ground pad, and
the signal line is located between the first ground pad and the second ground pad to form a ground-signal-ground (GSG) structure.

19. The optical module according to claim 18, wherein
the ground metal region of the substrate comprises a first ground metal region and a second ground metal region, and the high-frequency transmission line is located between the first ground metal region and the second ground metal region;
the heater is disposed on the first ground metal region, the ground terminal of the heater is wire-bonded to the first ground metal region, and the first ground pad is wire-bonded to the first ground metal region; and
the second ground pad is wire-bonded to the second ground metal region.

20. The optical module according to claim 1, further comprising a carrier, wherein the substrate is mounted on the carrier, and the carrier elevates a wire-bonding surface of the substrate to be flush with a surface of the circuit board.
